(19) United States
(12) Patent Application Publication
(10) Pub. No.: US 2015/0071020 A1
(43) Pub. Date: Mar. 12, 2015

(54) MEMORY DEVICE COMPRISING TILES WITH SHARED READ AND WRITE CIRCUITS

(71) Applicant: Sony Corporation, Tokyo (JP)

(72) Inventor: Jahanshir Javanifard, Carmichael, CA (US)

(21) Appl. No.: 14/186,437

(22) Filed: Feb. 21, 2014

Related U.S. Application Data
(60) Provisional application No. 61/874,406, filed on Sep. 6, 2013.

(51) Int. Cl. G11C 8/12; G11C 8/10

(52) U.S. Cl. CPC G11C 8/12; G11C 8/10
USPC 365/230.03

(57) ABSTRACT

A memory device comprising a plurality of simultaneously programmable banks, each bank comprising a plurality of memory tiles, each memory tile divided into a plurality of sub-tiles and a multi-level column and a multi-level row select for the plurality of memory tiles.

### CROSS-REFERENCE TO RELATED APPLICATION

This application claims benefit of U.S. Provisional Patent Application No. 61/874,406 filed Sep. 6, 2013, which is hereby incorporated in its entirety.

### FIELD

Certain embodiments of the disclosure relate to memory devices. More specifically, certain embodiments of the disclosure relate to a memory device comprising tiles with shared read and write circuits.

### BACKGROUND

Low power memory devices, such as conductive bridge random access memory (CBRAM) and other resistive RAM devices, are preferably used in mobile devices, as buffer memory for hard disks, BIOS memory or the like. Generally, memory devices comprise a plurality of tiles, each tile comprising an array of memory cells. A column select driver and a wordline select driver are used to write to or read from a particular bit in the tile. Each tile has a dedicated column select driver and a wordline select driver; the column select driver is generally unshared across tiles. This generally leads to a larger die size for larger capacity memory devices due to the increased number of tiles and circuits associated with each tile, leading to a reduction in array efficiency. However, it is desirable to reduce power consumption and die size to enable the use of memory devices in low power mobile devices to increase array efficiency.

Therefore, there is a need in the art for a memory device comprising tiles with shared read and write circuits.

### SUMMARY

An apparatus and/or method is provided for a memory device comprising sub-tiles with shared read and write circuits, as set forth more completely in the claims.

These and other features and advantages of the present disclosure may be appreciated from a review of the following detailed description of the present disclosure, along with the accompanying figures in which like reference numerals refer to like parts throughout.

### BRIEF DESCRIPTION OF THE DRAWINGS

FIG. 1 is a block diagram of a memory device in accordance with exemplary embodiments of the present invention

FIG. 2 is a block diagram of a tile in the memory device in accordance with exemplary embodiments of the present invention

FIG. 3 depicts four tiles in a memory device as an exemplary illustration of shared row decoder and control circuits;

FIG. 4 depicts a circuit diagram of a coupling of the tile of the memory device to the global column select and to the sense amps, program load and ground circuitry;

FIG. 5 is a depiction of the shared circuitry between a left tile and a right tile in accordance with exemplary embodiments of the present invention.

### DETAILED DESCRIPTION

According to exemplary embodiments of the present invention a memory device contains a plurality of memory tiles (or, pages). Each tile contains an array of memory cells. Each tile is further divided into a plurality of sub-tiles. In this embodiment read and write circuitry is shared between the pluralities of sub-tiles in the memory device. The sub-tiles in each tile are multiplexing the read and write circuitry between them. The read-write circuitry comprises a multi-level column select driver and a wordline select driver. The column select comprises three levels, and “level one select” decoders are common between four sub-tiles.

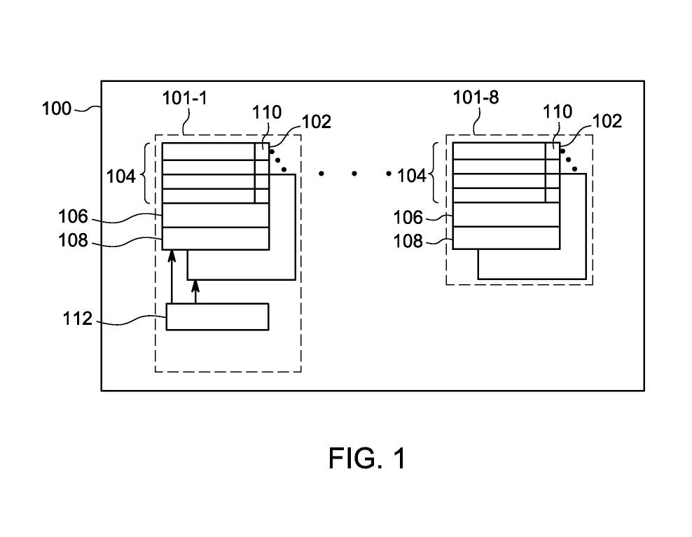

FIG. 1 is a block diagram of a memory device 100 in accordance with exemplary embodiments of the present invention.

The memory device 100 comprises a plurality of memory banks 101-1 to 101-8. According to one embodiment of the present invention, each bank can be enabled simultaneously, i.e., a set/reset or read pulse can be applied simultaneously across each bank 101-1 to 101-8. Each memory bank contains a plurality of tiles. Each tile, for example, tile 102, is associated with a respective sense amplifier 106 for reading the value of a selected memory cell in the tile 102. According to exemplary embodiments, each memory tile is divided into a plurality of sub-tiles, e.g. tile 102 is divided into subtiles 104. According to exemplary embodiments there may be “n” tiles in total in the memory device 100, where “n” is equal to 1024, for example, for the memory device 100 with a memory size of approximately 16 Gigabits (Gb). Each of the subtiles 104 comprises approximately 16 Megabits (Mb) of memory. Each tile 102 comprises 2048 word lines by 8192 bit lines in an exemplary embodiment. There are 256 global column selects for each bank 101-1 to 101-8, where each of the global column selects is coupled to 32 local bit lines.

According to exemplary embodiments, each tile 102 is divided into four sub-tiles. In one example, each of subtiles 104 comprises 2048 word lines by 2048 bit lines to access the 2048×2048 array of memory cells in the tile, though those of ordinary skill in the art will recognize that this is merely an exemplary configuration. In an exemplary embodiment, each memory cell is a buried recess access device (BRAD), though those of ordinary skill in the art will recognize that any type of memory cell may be used. Further, those of ordinary skill in the art will recognize that Figure does not show the physical configuration of each tile, sub-tile, bank or the like, but is merely a block representation showing the relationships between each memory bank, tile, sub-tile and the like.

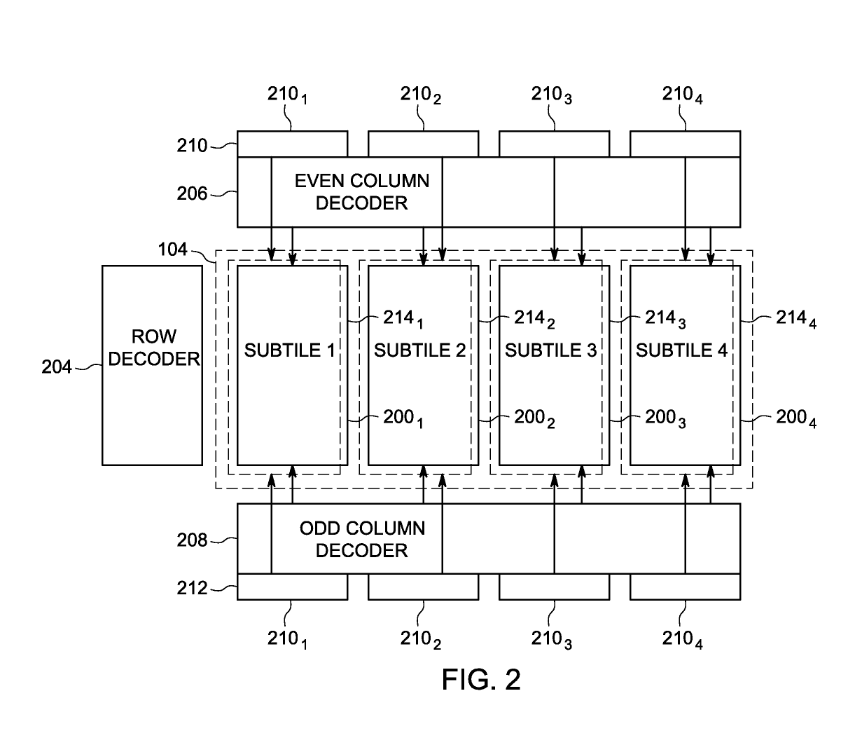

Word-lines are common to the four subtiles 104 in one tile, but common source lines (CSL) plates and the bit-line are not common across each sub-tile. Each of the sub-tiles 104 has an associated CSL plate as shown in FIG. 2. Each subtile 104 comprises error checking and correction (ECC) 64 bit-lines 110 (i.e., two 10 s). In this embodiment, 32 extra columns are in each subtile 104 for redundancy. A row pre-decoder 112 is shared between every 2 tiles, the row pre-decoder 112 decoding a memory address to selects two rows, one row in each of two adjacent tiles.

FIG. 2 is a block diagram of a tile 102 in the memory device 100 in accordance with exemplary embodiments of the present invention. The tile 102 comprises sub-tiles 200_{1 . . . 4}, row decoder 204, even column decoder 206, even odd column decoder 208, even column common source line (CSL) drivers 210_{1 . . .} ₄ and odd column CSL driver 212_{1 . . . 4}.

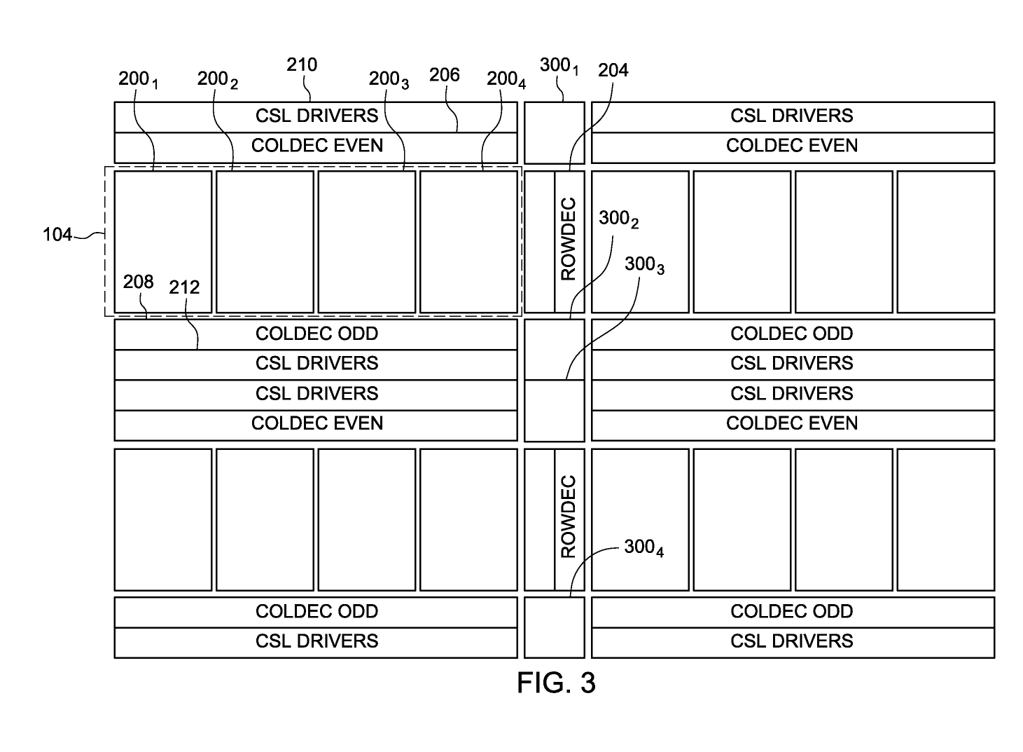

The row decoder 204 is common across two such tiles as shown in FIG. 3. In FIG. 2 only one tile is shown for simplicity. Therefore the row decoder 204 selects one sub-tile in the tile 102 and one sub-tile in another tile adjacent to tile 102.

The even column decoder 206 is located adjacent to the top of the tile 102 and the odd column decoder 208 is located adjacent to the bottom of the tile 102. The column decoder 206 decodes a memory address to activate particular bitlines on the tile 102. Those of ordinary skill in the art will recognize that the tile 102 is planar and the terms “top” and “bottom” are relative, referring to the top and bottom of the tile 102 when viewing the tile from a top-down view perpendicular to the plane of the tile 102.

According to exemplary embodiments, the CSL drivers 210 and 212 are inverters coupled to corresponding CSL plate 214_{1 . . . 4} above each sub-tile. The CSL drivers 210 and 212 drive each individual CSL plate 214_{1 . . . 4} to a particular voltage, for example the voltage required to perform a set operation (VSET), ground, or the like.

Initially, before any operations are performed on the sub-tiles 200_{1 . . . 4}, the even column decoder 206 and the odd column decoder 208 are driven to the potential of the CSL by coupling the CSL plates 214_{1 . . . 4} to the sub-tiles 200_{1 . . . 4}. Accordingly, when, for example, the odd column decoder 208 is either set to a high or low voltage, the resistance of cells in the adjacent even columns does not change, because the even columns are already raised to the CSL potential. Row decoding is performed on three levels, with a 16 bit wordline pitch. Column decoding is performed on two levels, with a 16 bit bitline pitch.

According to some embodiments, the wordline direction from the row decoder to the sub-tile 200₄ is 532.6 μm across, and the bit-line direction from the CSL driver 210 to the CSL driver 212, inclusive, is 193.2 μm. Sub-tiles 2001-₄ are measured at 488.6 μm across all sub-tiles, where each sub-tile is 166.5 μm wide in the bit-line direction. The column decoders 206 and 208 are 9.66 μm wide in the bit-line direction. The CSL drivers 210 and 212 are 1.2 μm wide in the bit-line direction. The row decoder 204 is 40 μm wide in the wordline direction. There is a 2 μm gap between the sub-tiles 200 and each of the column decoder 206, column decoder 208 and the row decoder 204. Each sub-tile has a 3.456 μm gap between the adjacent subtile. In this embodiment, the tile efficiency is determined as (166.5*445.19)/(193.23*532.6), or 72.025%. Those of ordinary skill in the art will recognize that the present invention is not limited to the present

FIG. 3 is a block diagram of a plurality of tiles in the memory device 100 in accordance with exemplary embodiments of the present invention.

FIG. 3 depicts four tiles in a memory device 104 as an exemplary illustration of shared row decoder 204 and control circuits 300_{1 . . . 4} (generally, control circuits 300). Each control circuit 300 comprises circuits for decoding a specific tile such as local column drivers for driving the column decoders 206 and 208 and the row decoder 204.

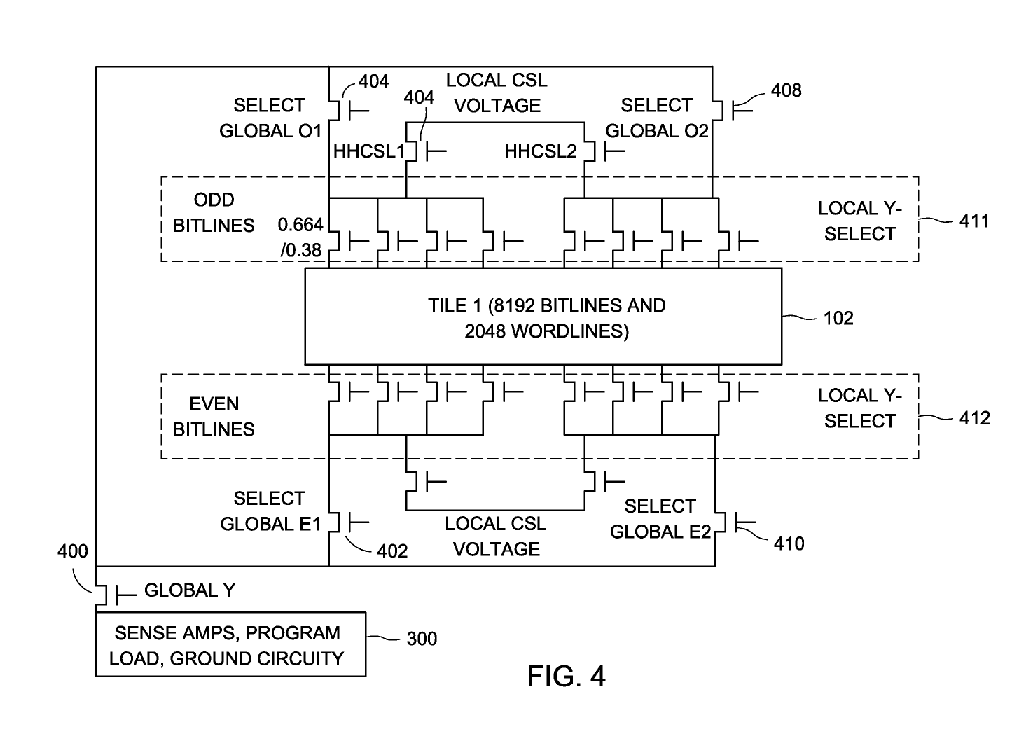

FIG. 4 depicts a circuit diagram of a coupling of the tile 102 of the memory device 100 to the global column select 400 and to the sense amps, program load and ground circuitry (i.e., control circuits 300).

The global column select 400 is further coupled to, for example, 16 other tiles, where one of the tiles is a redundancy tile. For simplicity, only tile 102 is shown. FIG. 4 depicts a multi-tiered column select comprising a first and second level of column selection. The global column select 400 selects one tile from the group of 17 tiles. The global column select 400 selects one tile and, further, one sub-tile from the selected tile. The global column select 400 may be referred to as a level 2 column select. The local column select 411 (for odd bitlines) or 412 (for even bitlines) is then selected to select columns across the tile 102. The local column select may be referred to as a level 1 column select.

Transistors 402 and 410 select even bitlines across all tiles in the memory device 100. Transistors 404 and 408 select odd bitlines across all tiles in the memory device 100. The local column select 411 and 412 are also couples to the CSL via transistors 420, 422, 424 and 426 to raise the bitlines to CSL potential when adjacent bitlines are raised to a SET voltage, in order for the adjacent memory cells across the bitlines to remain undisturbed.

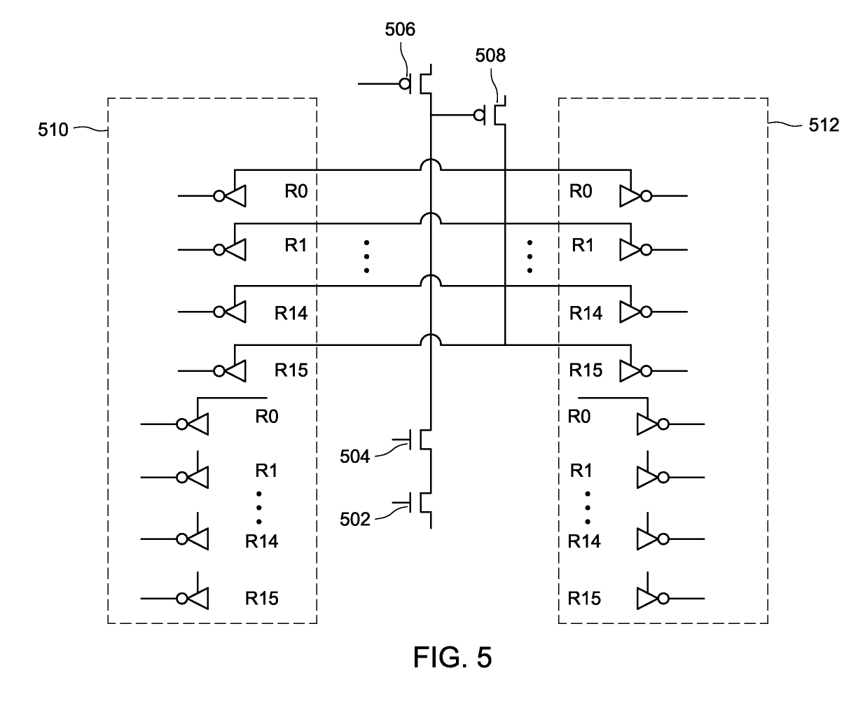

FIG. 5 is a depiction of the shared circuitry between a left tile 510 and a right tile 512 in accordance with exemplary embodiments of the present invention. FIG. 5 is a depiction of multi-tiered row selection comprising a first, second and third level of row select.

Tiles 510 and 512 are shown, sharing the row selection circuitry, transistors 502, 504, 506 and 508. In this embodiment, the left tile 510 and the right tile 512 comprise 32 rows of data, e.g., 32 wordlines across the tiles. A row decoder is shared between the left tile 510 and the right tile 512. Transistor 504 selects one out of every sixteen rows. Transistor 502 then selects 1 out of every 8 row from the rows selected by transistor 502. For example, if there are 2048 rows, transistor 504 will select 128 rows. Subsequently, transistor 502 selects 16 rows. One of these rows must be selected, so one of the values from an inverter coupled to a row goes high, the transistor 508 will go low, allowing the wordline to access one particular row.

While the present disclosure has been described with reference to certain embodiments, it will be understood by those skilled in the art that various changes may be made and equivalents may be substituted without departing from the scope of the present disclosure. In addition, many modifications may be made to adapt a particular situation or material to the teachings of the present disclosure without departing from its scope. Therefore, it is intended that the present disclosure not be limited to the particular embodiment disclosed, but that the present disclosure will include all embodiments falling within the scope of the appended claims.

What is claimed is:

1. A memory device comprising:
a plurality of simultaneously programmable banks, each bank comprising a plurality of memory tiles, each memory tile divided into a plurality of sub-tiles; and
a multi-level column and a multi-level row select for the plurality of memory tiles.

2. The memory device of claim 1, wherein each memory tile is divided into four sub-tiles.

3. The memory device of claim 2 wherein the multi-level column select is a two level column select comprising a first column select and a second column select.

4. The memory device of claim 3, wherein the first column select is a global column select, selecting a memory tile from the plurality of memory tiles.

5. The memory device of claim 4, wherein the second column select is a local column select, selecting one or more bitlines in the tile.

6. The memory device of claim 5, wherein the multi-level row select is a three-level column select, comprising a first row select, a second row select and a third row select.

7. The memory device of claim 6, wherein the first row select selects one of every sixteen rows for a total number of rows in a memory tile.

8. The memory device of claim 7, wherein the second row select selects one of every 8 rows from the selected one of every sixteen rows.

9. The memory device of claim 8, wherein the third row select selects one row out of every 8 rows for the memory tile.

10. The memory device of claim 1, wherein every two tiles share a common wordline.

11. The memory device of claim 1, wherein column decoders for each memory tile are separated into even and odd column decoders and placed opposite each other on the memory tile.

12. The memory device of claim 11, wherein common source line drivers are separated into even and odd drivers placed opposite each other on the memory tile.

13. The memory device of claim 12 further comprising a set of redundant memory tiles.
